(19) United States
(12) Patent Application Publication
(10) Pub. No.: US 2011/0262725 A1
(43) Pub. Date: Oct. 27, 2011

(54) Solar Control Glasses

(75) Inventor: Darryl J. Costin, Westlake, OH (US)

(73) Assignee: HIGH PERFORMANCE GLASS INNOVATIONS, LLC

(21) Appl. No.: 13/088,338

(22) Filed: Apr. 16, 2011

Related U.S. Application Data
(60) Provisional application No. 61/328,340, filed on Apr. 27, 2010.

(51) Int. Cl. B32B 7/02; C23C 16/44; C23C 16/52

(52) U.S. Cl. 428/212; 427/8

(57) ABSTRACT

Glass products that can significantly reduce the solar transmission of glass and thus improve the solar control properties for such products used in autos, trucks, homes and buildings. A significant reduction in total solar transmission of the coated glass product by depositing PVD stacked layer coatings on glasses which in and by themselves have light transmissions greater than 40% for building, 70% for autos and 80% for homes but which have the lowest solar transmission for a given level of visible transmission. Also, a selectivity in the base glass greater than 25 percentage points for a given level of visible transmission. Selectivity is defined as the percent visible transmission minus the percent solar transmission and can be expressed in units of percentage points. A selectivity greater than 30 percentage points is even more preferred.

This application claims priority from provisional application 61/328,340 filed Apr. 27, 2010, the contents of which are herewith incorporated by reference.

### BACKGROUND

In recent years, there has been a heightened interest in solar control glass for automotive, residential and commercial markets. Greater use of solar control glass in autos, homes and buildings could likely save over a hundred million tons of CO₂ emissions annually. Of course, the energy savings from greater use of such solar control glasses would be significant on a worldwide basis and dramatically reduce total energy requirements.

The glass industry introduced low emissivity glass to the marketplace over ten years ago and such glass has gained market share to a majority position over the years. The low emissivity glass keeps the heat inside the building or house by reflecting the long wavelength radiation back into the house. Hence, Low E glass reduces heating bills. However, the author believes that for the majority of climates in the world and certainly for southern regions, air conditioning or cooling costs dominate the energy cost equation. Hence, Low E glasses may be the wrong product since such products retain the heat inside the building. Instead, an improved product is solar control glasses that do not let the heat inside the building in the first place.

There are actually two means to reduce the solar transmission of glass. The first method is to deposit Physical Vapor Deposition (PVD) coating stacks on the glass that allow the transmission of visible light but reflect a portion of the solar radiation. The remaining solar energy is then transmitted through the glass, where a small part of the energy is absorbed and a smaller part of the energy is re-radiated back out of the glass. The second method is to use tinted or absorbing glass. The limitation in using traditional solar absorbing glasses in reducing solar transmission is that reducing the solar transmission is associated with a corresponding reduction in visible light transmission. The visible light transmission for automotive windshields is typically above 70% for windshields and sidelights, and about 80% for glass used in residential homes.

The current level of technology to achieve maximum solar control in glass is to use Physical Vapor Deposited (PVD) coatings on high visible transmission glass. This method would allows visible light to enter the home or building but repels a portion of the solar heat. Such coatings are typically made from layers of doped oxides and metal, for example, indium doped tin oxide and silver. Such PVD coatings are typically deposited on clear or slightly tinted glass which offer very little absorption. These solar control products rely specifically upon the ability of the PVD coating to reflect a portion of the solar radiation while allowing the visible light to enter. Once the optimum PVD coating is deposited on the glass, current commercial practice suggests that nothing more can be done to reduce solar transmission.

### INVENTION

The author has conceived of various glass products that can significantly reduce the solar transmission of glass and thus improve the solar control properties for such products used in autos, trucks, homes and buildings.

The first embodiment of the invention is to achieve a significant reduction in total solar transmission of the coated glass product by depositing PVD stacked layer coatings on glasses which in and by themselves have light transmissions greater than 40% for building, 70% for autos and 80% for homes but which have the lowest solar transmission for a given level of visible transmission.

A second embodiment of the invention is to achieve a selectivity in the base glass greater than 25 percentage points for a given level of visible transmission. Selectivity is defined as the percent visible transmission minus the percent solar transmission and can be expressed in units of percentage points. A selectivity greater than 30 percentage points is even more preferred.

The ideal base glass for autos and homes for example, would exhibit good near IR absorption characteristics for wavelengths greater than about 750 nanometers, but poor absorption characteristics in the electromagnetic spectrum where visible transmission is important, about 400-750 nanometers, which is a third embodiment of this invention.

The PVD coating would exhibit maximum solar reflection properties for a given level of visible transmission which is a fourth embodiment of this invention.

A fifth embodiment of the invention is to manipulate the total iron content and redox potential in the base glass so as to minimize the solar transmission for a given level of high visible transmission. The total iron is the percent Fe₂O₃ in the glass and the redox potential is the relationship between FeO and Fe₂O₃.

By way of a first example, the author has melted a glass with 0.71% total iron content with a 82.1% redox potential which is the ratio of the ferrous iron to total iron. This glass had a visible transmission of 41.8% with a very low solar transmission of 16.5%. So the selectivity was greater than 25 percentage points. Although this glass by itself would offer significant solar control, a major improvement would be realized by combining this super absorbing glass with a PVD stacked layer coating. Hence, if a PVD stacked layer coating (which filters solar radiation while maintaining high visible light transmission) were deposited on this glass, the visible light transmission could be as high as 40%, but the total solar control properties would be substantially improved compared to anything commercially available for that level of visible light transmission. This is true because this invention uniquely allows for the solar radiation first to be reflected and then a good portion of the remaining solar energy would be absorbed with the special low solar transmission glass. This novel glass configuration would produce unprecedented solar control for commercial building glass, which is yet another embodiment of this invention.

The same concept of achieving selectivity greater than 25-30 percentage points for the base glass could be used for high visible transmission glass for autos. By way of a second example and yet another embodiment of the invention, is to manipulate the total iron and redox potential of the base glass to maintain a selectivity greater than 25-30 percentage points with a minimum visible transmission of 70%. Then optimum PVD coatings could be deposited on this glass to achieve further solar control benefits would be realized for auto glass.

The same concept of achieving selectivity greater than 25-30 percentage points for the base glass could be used for high visible transmission glass for homes. By way of a third example and yet another embodiment of the invention, is to manipulate the total iron and redox potential of the base glass to maintain a selectivity greater than 25-30 percentage points with a minimum visible transmission of 80%. Then optimum PVD coatings could be deposited on this glass to achieve further solar control benefits for glass for homes.

Expanded use of these new solar control glass products throughout the world would reduce CO₂ emissions and reduce energy costs in a major and significant way. The same inventive concepts could be applied to glass for commercial buildings, autos and homes with different requirements for visible light transmission. Only the total iron and redox potential would need to be adjusted and perhaps minor modifications to the PVD stacked layer coatings.

Reducing the visible transmission specification for residential home glass from say 80% to less than 70% and preferably less than 60% would only marginally reduce the quality of the “see-through” characteristics of the glass when looking from the inside of the house to the outside. It simply would not be significant and probably only noticeable if an 80% visible light transmission glass were adjacent to the 60% visible transmission glass. However, the solar transmission would be markedly reduced. Since about half of the solar energy lies within the visible spectrum, reducing the visible light transmission in and by itself reduces the solar transmission. This is yet another embodiment of the invention—reduce the visible light transmission specification for residential home glass to 60-70% in order to reduce the solar transmission of such glass.

Since this invention deals with the optimization of several variables such as the visible light transmission, the solar transmission, the ferrous or FeO content of the glass, the total iron or Fe₂O₃ content of the glass, the redox potential, the degree of solar absorption of the glass, the degree of solar reflectance of the PVD coating and the specific thickness and composition of the PVD layers deposited on the glass, another embodiment is to utilize computer statistically designed experimental techniques to determine the level of interaction of these variables and then develop math models which describe the relationship between the solar properties and glass and coating properties. In this embodiment, the optimum solar control properties could be derived for products with different visible light transmission requirements. The methodology revealed is an embodiment and consists of the following steps:
1. The first step in the process of this invention and a critical embodiment is to select the best dependent variables with respect to optimizing the solar-optical properties of the coated glass. The prior art clearly teaches that the integrated solar transmission and the integrated visible transmission are the appropriate dependent variables to test in any experimental investigation attempting to optimize solar-optical properties of glass. However, the specific dopants and coatings in conventional automotive, residential and commercial glass products absorb the radiation at different wavelengths along the electromagnetic spectrum. For example, some dopants such as Fe₂O₃ exhibit the strongest absorption bands in the low wavelength UV range, whereas other compounds such as FeO exhibit the strongest absorption peaks in the near IR. So, contrary to the prior art, this invention teaches one to use the absorption at numerous wavelengths along the transmission curve as the dependent variable. Solar reflection then would represent the dependent variable for the PVD coating. Then, the integrated solar optical properties can be computed for a given experimental run. The use of HPGI's “Discrete Response Integrator” is an example of a method that can be used in this case.
2. The second step in the process of this invention and another embodiment is to select the proper independent variables for the base glass. The prior art discusses at length that during conventional glass melting, the Fe₂O₃ or the ferric oxide is reduced to some extent to FeO or the ferrous oxide, and that the balance of these two oxides is critical in controlling the solar-optical properties of glass. Therefore, the prior art teaches one to use the glass constituents as the independent variables in any experimental investigation and always report the relationship between the glass chemistry and the solar-optical properties. To achieve a certain level of visible transmission at a reduced solar transmission, the prior art discloses that the Fe₂O₃ concentration should be a certain value or range of values and the FeO concentration should be a certain value or range of values. However, the redox conditions that control the reduction of Fe₂O₃ to FeO are determined by the melting temperature, the air to fuel mixture, the amount of sulfur, the presence and concentration of reducing agents such as C and ZnS, and other factors. Therefore, it would be near impossible to treat FeO as the independent variable since it is so difficult to control and itself dependent upon a series of other variables. Contrary to the prior art, this invention uniquely teaches one to use the batch constituents as the independent variables in the experimental investigation.
3. The third step in the process of this invention and another embodiment is to select the proper independent variables for the PVD coating process. The prior art typically teaches to control the PVD coating thickness and composition. Contrary to the prior art, this invention uniquely teaches one to use the sputter coating process variables as the independent variables in the experimental investigation.
4. The fourth step in the process of this invention, and an embodiment in the invention is to employ statistically designed experiments, preferably D-Optimal designs, that given the number of independent variables, levels for each, and potentially significant interactions, determine the minimum number of experiments to run to obtain the required amount of information from which to model the transmission, reflection and absorption metrics with statistical significance. HPGI's “D-Optimal Matrix Creator” is an example of a specific software package to create such experimental designs.
5. The fifth step in the process of this invention and another embodiment is to develop predictive models for the quantitative relationship between the independent variables (the glass batch ingredients and the sputter coating process settings) the dependent variables, absorption at each wavelength and total solar reflection. The use of HPGI's “Multivariate Statistical Modeler” is an example of a software package that can be used to generate these equations using multiple regression techniques.
6. The sixth step in the process of this invention and another embodiment is to develop optimization models that can identify the batch chemistry and sputter coating process settings to the maximum solar absorption and reflection subject to various constraints, such as minimum visible transmission. For example, the optimization model should be able to determine the batch chemistry and sputter coating settings for the least solar transmission at a fixed visible transmission of say, 70%, subject to a specific range of a* and b*, say plus or minus 5 on the color scale. Yet another embodiment is to use the methodology of goal programming to simultaneously pursue coming as close as possible to multiple desirable properties. The use of HPGI's “Non Linear Property Optimizer” is an example of a model package that can be used to accomplish these embodiments.

What is claimed:

1. A method to reduce total solar transmission of glass products consisting of:
determining a series of coating layers produced from Physical Vapor Deposition and stacked on base glass which reflects the maximum amount of solar radiation without reducing visible transmission of the base glass by more than 10 percentage points, and
depositing the stacked layer PVD coatings on a base glass which exhibits a a difference between the visible transmission and total solar transmission greater than 25 percentage points.

2. A method as in claim 1 where the difference between the visible transmission and total solar transmission of the base glass is greater than 30 percentage points.

3. A method as in claim 1 where the visible transmission of the coated glass is a minimum of 40% and the total solar transmission is 10% maximum.

4. A method as in claim 1 where the visible transmission of the coated glass is a minimum of 60% and the total solar transmission is 27% maximum.

5. A method as in claim 1 where the visible transmission of the coated glass is a minimum of 70% and the total solar transmission is 32% maximum.

6. A method as in claim 1 where the visible transmission of the coated glass is a minimum of 80% and the total solar transmission is 38% maximum.

7. A method as in claim 1 where the maximum difference between the visible transmission and total solar transmission of the base glass is achieved by manipulating the total ferrous and ferric iron content in the base glass so as to minimize the solar transmission for a given level of high visible transmission.

8. A residential glass product according to claim 1 with a minimum visible transmission of 60% and maximum total solar transmission of 30%.

9. A residential glass product according to claim 1 with a minimum visible transmission of 70% and maximum total solar transmission of 35%.

10. A residential glass product according to claim 1 with a minimum visible transmission of 80% and a maximum total solar transmission of 40%.

11. A method as in claim 1 where the solar transmission of the coated glass is minimized for a given visible transmission by the steps of:
Conducting statistically designed experiments, and
Mathematically analyzing the results of such experiments, and
Developing quantitative models of the relationship between the dependent variables and the independent variables, and
Using optimization modeling techniques to identify the specific batch chemistry of the base glass and sputter coating process settings to achieve minimum total solar transmission for specific levels of visible transmission.

12. A method as in claim 11 where the dependent variables are the absorption at specific wavelengths for the base glass and the total solar reflection for the PVD coating.

13. A method as in claim 11 where the independent variables for the base glass is the specific levels of batch ingredients and the independent variables for the PVD coating is the specific sputter coating settings.
